(19) United States
(12) Patent Application Publication
(10) Pub. No.: US 2022/0013388 A1
(43) Pub. Date: Jan. 13, 2022

(54) PIN-LIFTER TEST SUBSTRATE

(71) Applicant: Lam Research Corporation, Fremont, CA (US)

(72) Inventors: John E. Daugherty, Fremont, CA (US); Changyou Jing, Livermore, CA (US); Sushil Anand, Fremont, CA (US)

(21) Appl. No.: 17/299,291

(22) PCT Filed: Dec. 3, 2018
(86) PCT No.: PCT/US2018/063652

§ 371 Date: Jun. 2, 2021

(51) Int. Cl. H01L 21/67; H01L 21/687

(52) U.S. Cl. CPC H01L 21/67259; H01L 21/68742; H01L 21/67253; H01L 21/67248; H01L 21/67288

(57) ABSTRACT

Various embodiments include apparatuses to provides an in-situ, non-intrusive verification of substrate pin-lifters while a substrate is in a substrate-processing location on a process tool. The disclosed subject matter can also verify any unexpected substrate movement prior to or while the substrate is being removed from the process tool. In an exemplary embodiment, a pin-lifter test substrate includes a number of motion sensors and at least one force sensor. The motion sensors including at least one type of sensor selected from sensor types including inclinometers and accelerometers. A memory device on the pin-lifter test substrate records data received from the motion sensors. Instead of or in addition to the memory device, a wireless communications device transmits data received from the motion sensors to a remote receiver. Other apparatuses and systems are disclosed.

### TECHNICAL FIELD

The subject matter disclosed herein relates to equipment used in the semiconductor and allied industries. More specifically, the disclosed subject matter relates to in-situ, non-intrusive verification of substrate pin-lifters while a substrate is in a substrate-processing location on a process tool, as well as a potential effect of malfunctioning substrate pin-lifters and related substrate-holding devices on dynamic alignment of a substrate. Therefore, the disclosed subject matter can verify operations of substrate pin-lifters and also verify any unexpected substrate movement while the substrate is being removed from the process tool.

### BACKGROUND

Generally, various pieces of semiconductor process equipment (e.g., deposition tools or etch tools) use three pressure-driven pin lifters to raise and lower semiconductor substrates (e.g., silicon wafers) onto or remove from an electrostatic chuck (ESC). The ESC is known to a person of ordinary skill in the art and is commonly used in, for example, plasma-based and vacuum-based semiconductor processing. The ESC is used to mount and electrostatically “clamp” a substrate during semiconductor processing but is also used to cool or heat substrates and provide flattening of the substrate to increase uniformity of processing.

A typical substrate pin-lifter is comprised of a number of pins (e.g., typically three pins comprising metal, sapphire, or metal tipped with sapphire), a pneumatic actuator to raise the substrate pin-lifters, and one or more position sensors to gauge a level of the substrate pin-lifters.

Any components in or related to the substrate pin-lifters that are out-of-specification, such as a broken or inoperable lift pin, too high or too low of air pressure, a misaligned or mis-calibrated pin-position sensor, etc., will disturb the handling of the substrate. If the substrate pin-lifters do not function correctly, the substrate could be damaged, resulting in financial loss due to devices on the substrate as well as downtime of the process tool to effect repairs.

Typically, a sequence of chucking and de-chucking operations includes the operations described below. A substrate is transferred into a processing module (PM) or a process chamber with an end-effector of a robotic arm. Generally, three substrate-lift pins move up and receive the substrate from the robotic arm while the pins are in a raised or “up” position. After the robotic arm is retracted from the process chamber, the substrate-lift pins move to a lowered or “down” position. The pins retract to just below (e.g., typically by just tens of microns) a top surface of the ESC, thereby leaving the substrate to land on a top, ceramic surface of the ESC. The ESC begins “chucking” the substrate by applying a high voltage to electrodes that are embedded inside the ceramic surface of the ESC (for conductor coulombic ESCs, both positive and negative voltages are applied). Once the process is completed, the high voltage applied to the ESC is reset to zero to remove all charges. The pins raise to the “up” position to lift the substrate and the robotic arm removes the substrate from the process chamber.

In addition to substrate pin-lifters that do not function correctly, electric charges are frequently trapped at or near the ESC surface, thereby creating residual chucking forces between the substrate and the ESC. When the pins are raised, during a substrate de-chucking operation, the residual chucking forces may cause unwanted substrate movement, such as bending, tilting, jumping, lateral sliding, and other movements that are potentially deleterious to semiconductor processing operations. In a worst-case scenario, the substrate may break while being separated from the ESC.

Currently, substrate pin-lifters are checked manually when the process chamber (or process module) is open. After the process chamber is closed and sealed, the substrate pin-lifters are monitored only through a pin sensor on one or more of the substrate pin-lifters. The pin sensor can only monitor whether a particular one of the substrate pin-lifters is raised (in an up position) or is lowered (in a down position). The pin sensor is unable to determine whether one or more of the substrate pin-lifters is broken, whether the air pressure is correct, or any of a number of other scenarios in which a failure has occurred (or is about to occur). For example, if one of the substrate pin-lifters is broken, the pin sensor may sense that the broken pin is in the correct position by sensing the position of the piston used to actuate the pin. However, the broken pin may cause the substrate to be in the incorrect position (e.g., lower on one side). Therefore, the substrate is in risk of being damaged (e.g., by the end effector of the robot, or being unable to be retracted by the robot). Either case can cause a substantial financial loss, especially on a fully-populated substrate that has nearly completed all front-end-of-line (FEOL) processes.

When the air pressure is incorrect, especially when too high, the substrate may also be subject to rough handling (e.g., high acceleration forces, potentially causing dynamic alignment (DA) issues of the substrate, as discussed below with regard to FIGS. 1A through 1C). Overall, there is currently no in-situ and automatic direct check on a location of the substrate.

Therefore, the disclosed subject matter provides an in-situ, non-intrusive verification of substrate pin-lifters while a substrate is in a substrate-processing location on a process tool (e.g., a substrate-processing system). The disclosed subject matter can also verify any unexpected substrate movement prior to or while the substrate is being removed from the process tool.

The information described in this section is provided to offer the skilled artisan a context for the following disclosed subject matter and should not be considered as admitted prior art.

### BRIEF DESCRIPTION OF THE FIGURES

FIGS. 1A-1C show examples of chucking and de-chucking operations and a resultant substrate lateral movement, with reference to an electrostatic chuck (ESC), due to at least one of (1) charge remaining on at least one of the substrate or the ESC during the de-chucking operation; or (2) one or more faulty pin lifters used to remove the substrate from the ESC;

FIG. 2A shows a plan view of one type of substrate—a silicon wafer;

FIG. 21B shows an example of sensors placed on the frontside of a pin-lifter test substrate (having the same or similar dimensions as the silicon wafer of FIG. 2A), in accordance with various embodiments disclosed herein;

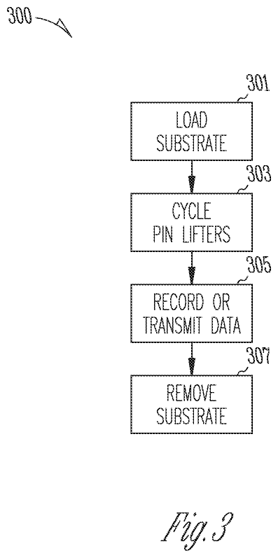

FIG. 2C shows an example of sensors placed on the backside of a pin-lifter test substrate (having the same or similar dimensions as the silicon wafer of FIG. 2A), in accordance with various embodiments disclosed herein; and

FIG. 3 shows an example of a method for receiving data from a pin-lifter test substrate of FIGS. 2B and 2C placed in a process chamber of a processing tool in accordance with various embodiments disclosed herein.

### DETAILED DESCRIPTION

The disclosed subject matter will now be described in detail with reference to a few general and specific embodiments as illustrated in various ones of the accompanying drawings. In the following description, numerous specific details are set forth in order to provide a thorough understanding of the disclosed subject matter. It will be apparent, however, to one skilled in the art, that the disclosed subject matter may be practiced without some or all of these specific details. In other instances, well-known process steps or structures have not been described in detail so as not to obscure the disclosed subject matter.

In various embodiments, a pin-lifter test substrate is a substrate having a number of sensors, described in detail below, to monitor various aspects of the substrate pin-lifters as well as movement of the substrate itself. The pin-lifter test substrate has an overall shape that is substantially similar or identical to a regular substrate used for, for example, producing semiconductor devices. Such a regular substrate may be, in certain embodiments, a 300 mm or 450 mm semiconductor (e.g., silicon) wafer. The pin-lifter test substrate can have the same tracking (e.g., laser marking and bar codes) and positioning (e.g., a notch on a 300 mm wafer) features as a regular substrate. The pin-lifter test substrate is placed in position (above the substrate pin-lifters) identically as a regular substrate by the end effector of a robotic arm of a standard transport robot.

The disclosed subject matter therefore provides direct measurement and the location of a substrate as would occur during actual substrate processing operations. The disclosed subject matter therefore provides an in-situ, non-intrusive automatic health-checking of substrate pin-lifters to prevent substrate loss, or to reduce or minimize downtime of a process tool. Therefore, the disclosed subject matter provides an in-situ, non-intrusive verification of substrate pin-lifters while a substrate is in a substrate-processing location on a process tool. The disclosed subject matter can also verify any unexpected substrate movement while the substrate is being removed from the process tool.

In various embodiments, the pin-lifter test substrate disclosed herein may include, for example, various types of motion sensors, force sensors, and data acquisition systems. As described in more detail below, each of these components is mounted on the pin-lifter test substrate.

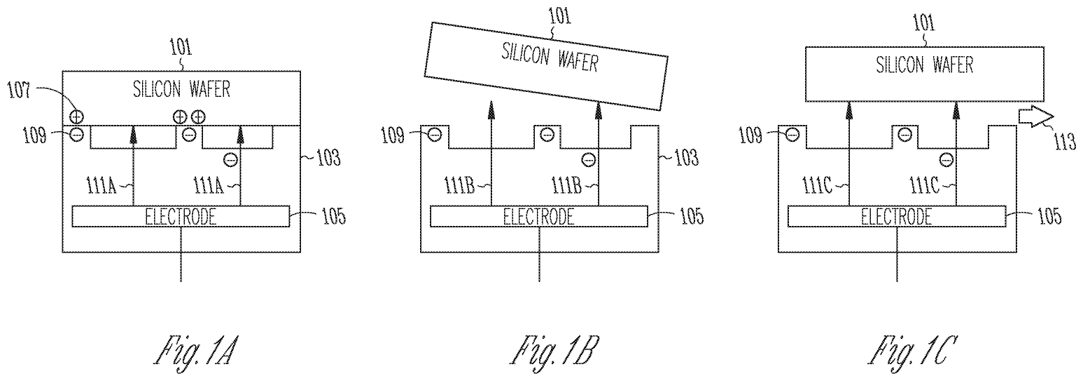

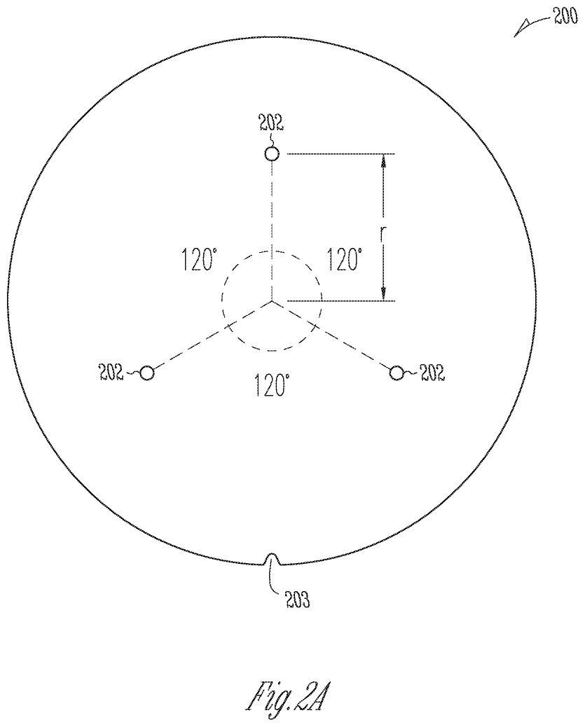

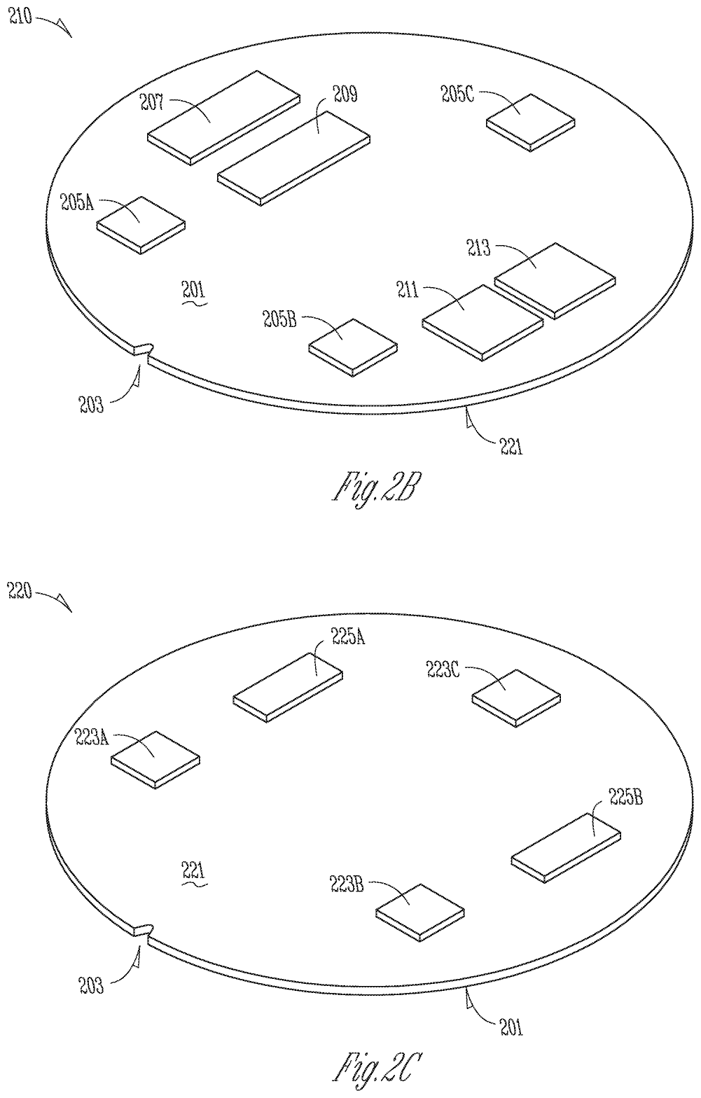

As an example of one function of the motion sensors on the pin-lifter test substrate, FIGS. 1A through 1C show examples of possible substrate movement during a de-chuck operation. Such substrate movement can be monitored and recorded with various embodiments of the disclosed pin-lifter test substrate. For example, with reference now to FIGS. 1A through 1C, examples of chucking and de-chucking operations and a resultant substrate lateral movement, with reference to an electrostatic chuck (ESC), due to at least one of (1) charge remaining on at least one of the substrate or the ESC during the de-chucking operation; or (2) one or more faulty pin lifters used to remove the substrate from the ESC.

With reference to a chucking operation of FIG. 1A, a silicon wafer 101 (or the pin-lifter test substrate, described below) is placed on an electrostatic chuck (ESC) 103. The ESC 103 has at least one electrode 105, to apply a voltage to the ESC 103, and multiple substrate pin-lifters (pins), shown in a lowered position 111A. In the lowered position 111A, the pins are generally tens of microns below an uppermost surface of the ESC 103. However, an exact distance below the uppermost surface has no effect on the performance or functioning of the disclosed subject matter provided that the silicon wafer 101 is in contact, or near contact, with the uppermost surface of the ESC 103 during a chucking operation. A person of ordinary skill in the art will recognize, based upon reading and understanding the disclosure provided herein, that the disclosed subject matter may apply equally to any type of substrate used in the semiconductor and allied industries. Therefore, the substrate need not be limited to only silicon wafers. However, the term “silicon wafer” will be used herein merely for clarity to describe various aspect of the disclosed subject matter.

A high voltage is applied to the electrode 105, which in turn delivers the high voltage to the ESC 103. The applied high voltage creates opposite sign charges between the silicon wafer 101 and the ESC 103. In this example, a negative charge 109 is formed on the ESC 103 and a positive charge 107 is formed on a surface of the silicon wafer 101 that is proximate to the ESC 103 (wafer charges redistribute primarily on a lowermost portion of the silicon wafer 101 proximate to the ESC 103). Consequently, the applied high voltage from the electrode 105 creates an electrostatic force holding the silicon wafer 101 onto the ESC 103.

In a typical process flow, after the silicon wafer 101 is chucked by the electrostatic force to the ESC 103, helium gas is delivered (e.g., to increase thermal conductivity for heating and cooling of the silicon wafer 101) to the backside of the silicon wafer 101 (i.e., the side of the wafer proximate to the ESC 103) prior to the start of a desired process recipe as executed by, for example, a controller within the process tool. As will be understood by a person of ordinary skill in the art and as described in more detail below, the pin-lifter test substrate can also be configured to recognize a pressure and flow of the helium gas. After the process recipe is completed, the helium gas flow stops, and the helium is then pumped out (evacuated). The high voltage of the electrode 105 is reset to zero to, ideally, remove all charges.

With reference now to FIG. 1B, after the helium is evacuated and the high voltage on the electrode 105 is reset to zero volts, the pins move from the lowered position 111A to a raised position 111B. In the raised position 111B, the pins lift the silicon wafer 101 to a fixed “up” position. In the up position, the robotic arm can move back into the process chamber to pick up and remove the silicon wafer 101.

However, as noted in FIG. 1B, if there is still remaining charge on portions of the silicon wafer 101 or the ESC 103, the silicon wafer 101 may not lift properly above the ESC 103 when the pins are in the raised position 111B due to residual attractive forces, including for example, charge trapping, and migration of charges. Consequently, due to the attractive forces, the silicon wafer 101 may move laterally and/or rotationally with reference to the ESC 103 as shown in FIG. 1C. The lateral and/or rotational shift causes a dynamic-alignment (DA) offset 113. Overall, dynamic alignment measures a position of the silicon wafer 101 as the silicon wafer 101 moves into or out of the process chamber. The DA offset 113 is a difference between the silicon wafer 101 before the process begins versus after the process is completed (that is, DA before process—DA after process). The DA offset 113 monitors a quality of the wafer de-chuck.

As discussed briefly above, at ESC operating-temperatures, which may be several hundred degrees Celsius, electric charge can become trapped at an uppermost surface of the ESC 103 during a wafer chucking operation. The trapped charges are also referred to as residual charges. Furthermore, various emissions from the silicon wafer 101 may also be a factor in residual forces occurring between the silicon wafer 101 and the ESC 103. These residual forces can cause unwanted wafer movement, such as bending, tilting, jumping, sliding, or even breakage of the wafer.

A specific de-chuck failure-root-cause analysis can be complex, depending on process, wafer type, ESC ceramic material, ceramic temperature, process time, bias voltage, process chemistries, and other factors. For example, as is known to a person of ordinary skill in the art, there are two main types of ESC used in the semiconductor and allied industries—a coulombic-type chuck and a Johnsen-Rahbek type of chuck. One significant difference between the two chuck types relates to de-chuck operations. In a coulomb-type chuck, once the high voltage on the electrode 105 is reset to zero volts, a nearly-instantaneous and large short-circuit current flows, but decreases exponentially with a short time constant (on the order of milliseconds). However, in a Johnsen-Rahbek type of chuck, a non-exponentially decaying small current is sustained for much longer time (on the order of seconds), thereby potentially causing a much longer de-chuck time due to the time required for residual charges to dissipate.

FIG. 2A shows a plan view of one type of substrate—a silicon wafer 200. The silicon wafer 200 may be the same as, or similar to, the silicon wafer 101 described as part of the ESC de-chuck process above. In this particular case, the silicon wafer 200 may be considered to be a 300 mm wafer. The silicon wafer 200 is shown to include a notch 203. In a specific exemplary embodiment, both the silicon wafer 200 and the notch 203 are formed in compliance with international wafer standard SEMI M1-1107, SPECIFICATIONS FOR POLISHED SINGLE CRYSTAL SILICON WAFERS (available from Semiconductor Equipment and Materials International (SEMI™) at www.semi.org).

The silicon wafer 200 also shows an exemplary embodiment of relative locations of three substrate pin-lifters that contact the silicon wafer 200 on a bottom side of the wafer. In this exemplary embodiment, the three substrate pin-lifters are located 120° from one another, each at a distance “r” from a center-most portion of the silicon wafer 200. However, a person of ordinary skill in the art will recognize that more than three substrate pin-lifters may be used and at locations other than those shown in FIG. 2A.

FIG. 2B shows an example of sensors placed on the frontside of a pin-lifter test substrate 210 in accordance with various embodiments disclosed herein. In this embodiment, the pin-lifter test substrate 210 has the same or similar dimensions as the silicon wafer of FIG. 2A. For example, according to SEMI™ standard specifications, a 300 mm silicon wafer has a diameter of 300 mm±0.2 mm, a thickness of 775±25 μm, and specific dimensions for the wafer notch (see SEMI M1-1107).

Although the maximum thickness of the SEMI standard for a 300 mm silicon wafer is 800 μm, many process chambers can accept a substrate up to at least 2 mm in thickness while some process chambers allow a substrate thickness of up to 5 mm. Therefore, in various embodiments described herein, the thickness of the pin-lifter test substrate can be up to at least 2 mm or even 5 mm depending upon a particular process chamber for which the pin-lifter test substrate is designed. Also, a standard 300 mm wafer has a mass of about 90 grams (depending on an exact diameter and thickness of the silicon wafer). If the pin-lifter test substrate is substantially heavier than a standard silicon wafer (for this example, the 90 grams of a 300 mm wafer), the mass of the pin-lifter test substrate substantially over about 90 grams may disturb or change the behavior of the substrate pin-lifters. Therefore, the mass of the pin-lifter test substrate may be chosen to be close to the mass of a standard substrate (e.g., the 90 grams of a 300 mm silicon wafer). However, a difference in mass is acceptable and the substrate pin-lifters can be calibrated for the added mass, as is known to a person of ordinary skill in the art, such that the mass of the pin-lifter test substrate can be corrected on a particular tool under test.

However, upon reading and understanding the disclosure provided herein, a skilled artisan will recognize that the pin-lifter test substrate 210 of FIG. 2B may be formed to comply with any form that is the same as or similar to actual substrates used in a fabrication facility. For example, the pin-lifter test substrate 210 of FIG. 211 may take the form of a 200 mm wafer, a 450 mm wafer, a 150 mm square by 6.35 mm (approximately 6 inches square by 0.25 inch) photomask (with or without a pellicle), a flat panel display (of various sizes) or any other type of substrate known in the art.

The pin-lifter test substrate 210 of FIG. 2B may be formed from various materials including, for example, stainless steel, aluminum and alloys thereof, various types of ceramics (e.g., aluminum oxide, Al₂O₃), or any other type of material that can be formed substantially in accordance with the physical characteristics described herein. In a specific exemplary embodiment, the pin-lifter test substrate of FIG. 2B can be a 300 mm silicon wafer that includes at least some of the various sensors described below. Such a wafer including at least some of the sensors may be considered to be an instrumented wafer.

In one embodiment, the pin-lifter test substrate 210 includes a number of different types of sensors formed on a top face 201 of the pin-lifter test substrate 210. For example, the pin-lifter test substrate 210 is shown to include various types of motion sensors 205A, 205B, 205C, a memory device 207, a wireless communications device 209, a power-management device 211, and a power supply 213.

In an embodiment, the motion sensors 205A, 205B, 205C are placed at or near a location of the substrate pin-lifters. The motion sensors 205A, 205B, 205C can be placed either on the top face 201 and/or a bottom face 221 of the pin-lifter test substrate 210. In this particular embodiment, there are three motion sensors 205A. 205B, 205C since there are typically three substrate pin-lifters used with a semiconductor wafer. However, there may be more than three substrate pin-lifters when used with, for example, a flat panel display, which use more than three substrate pin-lifters.

At least one of the motion sensors 205A, 205B, 205C may comprise one of more types of sensors including inclinometers and accelerometers. As is known to a skilled artisan, an inclinometer can be used to determine if the pin-lifter test substrate 210 is level, a slope or tilt of the pin-lifter test substrate 210, or a localized depression (e.g., bow or warp) of the pin-lifter test substrate 210. An accelerometer may be used to determine an acceleration (e.g., linear and/or angular) of the pin-lifter test substrate 210. For example, the accelerometer can be used to determine how quickly the pin-lifter test substrate 210 is applied onto the substrate pin-lifters or how quickly the pin-lifter test substrate 210 is released from the substrate pin-lifters due to attractive forces from an ESC failing to release the pin-lifter test substrate 210 when expected. For example, while the substrate pin-lifters are moving to either a raised wafer position (“up” position) or lowered position (“down” position), a maximum acceleration of the lift pins can be as large as one “G” (9.8 m/sec²). This large acceleration can result in the DA offset as described above with reference to FIGS. 1A through 1C.

The accelerometer can also be used to measure vibrations on the pin-lifter test substrate 210. In a specific exemplary embodiment, at least one of the motion sensors 205A, 205B, 205C may comprise, for example, a piezoelectric-driven diaphragm to test de-chuck operations as described above with reference to FIGS. 1A through 1C and may include a MEMS-based force sensors (or other type of force sensors known in the relevant art, such as, e.g., a strain gauge) to check a force applied by the electrostatic chuck.

In various embodiments, the memory device 207 may comprise a non-volatile memory device (e.g., flash memory, phase-change memory, etc.). In other embodiments, the memory device 207 may be a volatile memory device and powered by the power supply 213.

The wireless communications device 209 may include various types of wireless communications devices known in the art including, for example, radio-frequency transceivers, Bluetooth® transceivers, infrared (IR) and other types of optical-communications transceivers, etc. As will be recognizable to a person of ordinary skill in the art upon reading and understanding the disclosure provided herein, the transceivers may have a transmitting function only. In this case, the wireless communications device 209 may be considered to be a transmitter only.

In certain embodiments, the pin-lifter test substrate 210 may have either the wireless communications device 209 or the memory device 207, but not both. In other embodiments, the pin-lifter test substrate 210 may include both the wireless communications device 209 and the memory device 207. As described in more detail below, in certain applications of the pin-lifter test substrate 210, the wireless communications device 209 may not function if the pin-lifter test substrate 210 is removed from the robot after being placed within the process chamber and closing the process chamber access door (due to the electromagnetic shielding effect of the fully-closed process chamber). In this case, the memory device 207 is used to record all data available from the pin-lifter test substrate 210 for later processing.

The power-management device 211 may comprise, for example, various types of integrated circuit (IC) power-management devices. The power-management device 211 can include functions such as DC-to-DC conversion circuits (e.g., for supplying various bias voltages for the various devices mounted on the pin-lifter test substrate 210), battery-charging functions for the power supply 213, voltage-scaling functions (e.g., including charge pumps for the memory device 207), and other functions known in the relevant art.

The power supply 213 may comprise various types of batteries or related energy-storage technologies to deliver power to various components (e.g., the wireless communications device 209, the memory device 207 for retaining data if needed (e.g., for volatile memory devices), sense amps for reading to and writing from the memory device 207, etc.).

Referring now to FIG. 2C, an example of sensors formed on a bottom face 221 of a pin-lifter test substrate 220, in accordance with various embodiments disclosed herein, is shown. The pin-lifter test substrate 220 is shown to include force sensors 223A, 223B, 223C as well as a first additional sensor 225A and a second additional sensor 225B. As described below, in one embodiment, the first additional sensor 225A and the second additional sensor 2251B may comprise the same type of sensor. In other embodiments, the first additional sensor 225A and the second additional sensor 225B may comprise different types of sensors.

In an embodiment, the force sensors 223A, 223B, 223C are placed at or near a location of the substrate pin-lifters. The force sensors 223A, 223B, 223C can be placed either on the top face 201 and/or a bottom face 221 of the pin-lifter test substrate 210, 220. In this particular embodiment, there are three force sensors 223A, 223B, 223C since there are typically three substrate pin-lifters used with a semiconductor wafer. However, there may be more than three substrate pin-lifters when used with, for example, a flat panel display. Consequently, there may be more than three force sensors.

At least one of the force sensors 223A, 223B, 223C may comprise strain gauges, such as the MEMS-based strain gauge described above with reference to FIG. 2B (or other type of strain gauge known in the relevant art).

The first additional sensor 225A and the second additional sensor 225B may comprise one or more sensors including, for example, a temperature sensor, a pressure sensor, and a flow sensor. The temperature sensor can be used to check temperature uniformity in various locations of the pin-lifter test substrate 220. The pressure sensor may comprise, for example, various types of digital pressure transducers, including pressure-transducer arrays, and piezometers known in the art, and can monitor, for example, a helium pressure applied on the backside of a substrate once attached to the ESC. Similarly, the flow sensor may comprise, for example, a laminar-flow meter or a hot-wire anemometer, and can be used to monitor gas flow on the backside, or frontside, of the pin-lifter test substrate 210, 220.

Although only two additional sensors are shown, a skilled artisan will understand that any number of additional sensors may be included. For example, each temperature sensor may comprise a number of thermocouples or resistance-temperature detectors (RTDs, including thin-film RTDs) embedded in the bottom face 221 of the pin-lifter test substrate 220.

In various embodiments, and although not shown explicitly but readily understandable to a person of ordinary skill in the art based upon reading and understanding the disclosure provided herein, the pin-lifter test substrate 210, 220 of FIGS. 2A and 2B may also include a microprocessor to provide a number of control functions to each of the sensors and other devices mounted on the pin-lifter test substrate 210, 220. For example, the microprocessor may be used to provide encoding and decoding of memory, parity checks of memory, data management and communications management, conversion of volumetric-flow rates to mass-flow rates, and other functions known to a skilled artisan.

With reference now to FIG. 3, an example of a method 300 for receiving data from the pin-lifter test substrate of FIGS. 2B and 2C placed in a process chamber of a processing tool in accordance with various embodiments disclosed herein is shown. As will be understandable to a person of ordinary skill in the art, any or all of the method steps described herein may be executed by, for example, a controller of the process tool.

At operation 301, the pin-lifter test substrate is loaded into the process chamber by the end effector of a robot. The pin-lifter test substrate may be loaded into the process chamber (or process module) either before or after, for example, an actual boat or FOUP of product substrates. The pin-lifter test substrate may be used to check a condition of the process tool as described above on a periodic basis (e.g., once per shift, once per week, as a portion of a normal preventive maintenance schedule, etc.).

In this particular embodiment, once the end effector places the pin-lifter test substrate onto the substrate-holding device (e.g., an ESC) within the process chamber, the robot arm stays in the process chamber. The robot therefore does not retract.

At operation 303, the substrate pin-lifters are commanded (through the user interface of the process tool) to move up (to a raised, pins-up position) and down (to a lowered, pins-down position) for a predetermined number of cycles per a predetermined pattern. For example, the predetermined pattern may move each of the pins one-by-one, sequentially, and then in groups of two or three pins.

At operation 305, various ones of the sensors on the pin-lifter test substrate, for example, the motion sensors and force sensors, either record to the memory device 207 and/or transmit the data through the wireless communications device 209 (see FIG. 2B) including motion data (e.g., up/down acceleration, incline angles, etc.) and force data, to a remote receiver. The remote receiver may be located on, for example, the robotic arm or at another location outside of the process chamber.

At operation 307, after all of the substrate pin-lifters are in a down or lowered position, the robot retracts the pin-lifter test substrate and moves the pin-lifter test substrate out of the process chamber. Note that, in this embodiment, the robot stays in the process chamber during testing. Therefore, the end effector of the robot is always under the pin-lifter test substrate. Consequently, even if, for example, one or more of the substrate pin-lifters is broken, there is no risk of being unable to remove the pin-lifter test substrate from the process chamber. Data from the pin-lifter test substrate are retrieved (e.g., in the memory device 207) and can be processed to identify problems with the substrate pin-lifters and related components (e.g., the ESC).

For example, the method 300 can be used to identify at least the following problems:
Whether the pin-lifter test substrate indicates any DA issues based on lateral and/or rotational movement of the pin-lifter test substrate either when placed on the ESC or removed from the ESC;
Whether one or more of the substrate pin-lifters is broken;
Whether an air hose coupled to the pin lifter may be broken;
Whether there is no contacting force from the pin-lifter test substrate to the substrate holder (e.g., the ESC);
Whether air pressure feeding the substrate pin-lifters is too high (thereby increasing acceleration beyond specification for an expected high-end range and possibly increasing vibration as well);
Whether the air pressure is too low if the acceleration is out of specification for an expected low-end range;
Whether the substrate pin-lifters may not be leveled if the incline angles are not in specification or angles from different locations vary beyond specification;
Whether the substrate pin-lifters are not all similarly accelerating (in accordance with, for example, a predetermined tolerance value or specification quantifier) based on a determination that the accelerations from different locations vary too much; and/or
Whether position sensors mounted on one or more of the substrate pin-lifters are not functioning properly based on a determination that the data from the position sensor do not match the predetermined pattern of cycling the pins, for example, as applied at operation 303, as compared with a reconstructed-movement sequence based on data retrieved from (and/or transmitted by) the pin-lifter test substrate motion data.

Alternative embodiments to the method of FIG. 3 include, for example, rather than programming the robot to stay in the process chamber during testing, a regular wafer-handling robot program can be used for the convenience of users. Therefore, in this embodiment the robot is retracted from the process chamber during testing with the pin-lifter test substrate of FIGS. 2A and 2B. However, retracting the robot may pose a risk of, for example, not being able to remove the pin-lifter test substrate out of the process chamber if, for example, one or more of the pin-lifter test substrate is not functioning properly. Also in this embodiment, rather than relying on either off-line data retrieval and processing (from the memory device 207 0f FIG. 2B) or wireless data being transmitted to a wireless receiver (e.g., mounted on the robot while still in the process chamber), a real-time wireless data-stream may be possible if the faraday-cage effect (e.g., electromagnetic shielding) of the process chamber can be overcome with the access door to the process chamber being closed while the pin-lifter test substrate is inside the process chamber.

In various embodiments, the method 300 of FIG. 3 can also include programming the end-effector of the robot to initially remain in the process chamber to perform a “health test” of the substrate pin-lifters to verify that there is little to no risk of being unable to remove the pin-lifter test substrate. After confirming a good health of the substrate pin-lifters, this embodiment of the method 300 includes programming the robot to retract from the process chamber, leaving the pin-lifter test substrate in the process chamber, applying vacuum to the process chamber, and performing additional testing. The additional testing may include, for example, a helium-flow test, a helium-pressure test, or other tests that require vacuum conditions within the process chamber, or conditions that will not allow the robot to remain in the process chamber.

Overall, the disclosed subject matter contained herein describes or relates generally to operations of “tools” in a semiconductor fabrication environment (fab). Such tools can include various types of deposition (including plasma-based tools such as ALD (atomic layer deposition), CVD (chemical vapor deposition), PECVD (plasma-enhanced CVD), etc.) and etching tools (e.g., reactive-ion etching (RIE) tools), as well as various types of thermal furnaces (e.g., such as rapid thermal annealing and oxidation), ion implantation, and a variety of other process and metrology tools found in various fabs and known to a person of ordinary skill in the art. However, the disclosed subject matter is not limited to semiconductor environments and can be used in a number of machine-tool environments such as robotic assembly, manufacturing, and machining environments.

Upon reading and understanding the disclosure provided herein, a person of ordinary skill in the art will recognize that various embodiments of the disclosed subject matter may be used with other types of substrate-holding devices, in addition to an ESC. For example, various types of cleaning, metrology, and process tools used in the semiconductor and allied industries use, for example, vacuum-controlled substrate-holding devices. For example, various types of substrate-holding devices may have problems with substrate sticking or otherwise adhering to the substrate-holding devices due to forces such as molecular adhesion, Van der Waal forces, electrostatic forces, and other near-field contact forces. Therefore, as described, various embodiments of the disclosed subject matter provide for a pin-lifter test substrate that can be used to monitor various types of process tools and other substrate handling tools as described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein, the term “or” may be construed in an inclusive or exclusive sense. Further, other embodiments will be understood by a person of ordinary skill in the art upon reading and understanding the disclosure provided. Further, upon reading and understanding the disclosure provided herein, the person of ordinary skill in the art will readily understand that various combinations of the techniques and examples provided herein may all be applied in various combinations.

Although various embodiments are discussed separately, these separate embodiments are not intended to be considered as independent techniques or designs. As indicated above, each of the various portions may be inter-related and each may be used separately or in combination with other embodiments discussed herein. For example, although various embodiments of methods, operations, and processes have been described, these methods, operations, and processes may be used either separately or in various combinations.

Consequently, many modifications and variations can be made, as will be apparent to a person of ordinary skill in the art upon reading and understanding the disclosure provided herein. For example, in various embodiments, and with reference to FIGS. 2A and 2B, each of the various motion sensors, force sensors, the memory device, and the communications device may be assembled directly on the pin-lifter test substrate. In other embodiments, each of the various motion sensors, force sensors, the memory device, and the communications device may be assembled or otherwise formed directly on a printed-circuit board that is then mounted onto the pin-lifter test substrate. In still other embodiments, some of the various motion sensors, force sensors, the memory device, and the communications device may be assembled directly on the pin-lifter test substrate while other components are assembled directly on a printed-circuit board that is then mounted onto the pin-lifter test substrate.

Moreover, functionally equivalent methods and devices within the scope of the disclosure, in addition to those enumerated herein, will be apparent to the skilled artisan from the foregoing descriptions. Portions and features of some embodiments may be included in, or substituted for, those of others. Such modifications and variations are intended to fall within a scope of the appended claims. Therefore, the present disclosure is to be limited only by the terms of the appended claims, along with the full scope of equivalents to which such claims are entitled. It is also to be understood that the terminology used herein is for the purpose of describing particular embodiments only and is not intended to be limiting.

The Abstract of the Disclosure is provided to allow the reader to quickly ascertain the nature of the technical disclosure. The abstract is submitted with the understanding that it will not be used to interpret or limit the claims. In addition, in the foregoing Detailed Description, it may be seen that various features may be grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

What is claimed is:

1. A pin-lifter test substrate system, comprising:
a plurality of motion sensors, the motion sensors including at least one type of sensor selected from sensor types including inclinometers and accelerometers;
one or more force sensors located in proximity to corresponding locations of a plurality of substrate pin-lifters when the pin-lifter test substrate is placed on a substrate-holding device;
a communications device configured to transmit data received from the plurality of motion sensors and the one or more force sensors; and
a memory device communicatively coupled to the communications device and configured to record data received from the plurality of motion sensors and the one or more force sensors.

2. The pin-lifter test substrate system of claim 1, wherein the pin-lifter test substrate has the same or similar dimensions as a silicon wafer.

3. The pin-lifter test substrate system of claim 1, wherein the pin-lifter test substrate is formed from at least one material selected from materials including stainless steel, aluminum and alloys thereof, and various types of ceramics.

4. The pin-lifter test substrate system of claim 1, wherein the inclinometers are configured to determine a slope or tilt of the pin-lifter test substrate.

5. The pin-lifter test substrate system of claim 1, wherein the inclinometers are configured to determine a localized depression of the pin-lifter test substrate.

6. The pin-lifter test substrate system of claim 1, wherein the inclinometers are configured to determine whether one or more of a plurality of substrate pin-lifters on a substrate-holding device is broken.

7. The pin-lifter test substrate system of claim 1, wherein the one or more force sensors are configured to determine whether there is a contacting force from the pin-lifter test substrate to the substrate-holding device.

8. The pin-lifter test substrate system of claim 1, wherein the accelerometers are configured to determine whether air pressure feeding the plurality of substrate pin-lifters is too high.

9. The pin-lifter test substrate system of claim 1, wherein the accelerometers are configured to determine whether air pressure feeding the plurality of substrate pin-lifters is too low.

10. The pin-lifter test substrate system of claim 1, wherein the accelerometers are configured to measure vibrations on the pin-lifter test substrate.

11. The pin-lifter test substrate system of claim 1, wherein the communications device is a wireless communications device configured to transmit data received from the plurality of motion sensors and the one or more force sensors to a remote receiver.

12. The pin-lifter test substrate system of claim 11, wherein the wireless communications device is selected from at least one type of wireless communications device including radio-frequency transmitters, Bluetooth transmitters, infrared (IR) transmitters, and optical-communications transmitters.

13. The pin-lifter test substrate system of claim 1, further comprising at least one additional sensor including at least sensor type selected from a temperature sensor, a pressure sensor, and a flow sensor.

14. The pin-lifter test substrate system of claim 13, wherein the temperature sensor includes a plurality of temperature sensors that are configured to determine a temperature from various locations of the pin-lifter test substrate.

15. The pin-lifter test substrate system of claim 13, wherein the pressure sensor is configured to determine a gas pressure applied on a backside of the pin-lifter test substrate.

16. The pin-lifter test substrate system of claim 1, wherein the plurality of motion sensors, the one or more force sensors, the memory device, and the communications device are directly assembled on the pin-lifter test substrate.

17. The pin-lifter test substrate system of claim 1, wherein the plurality of motion sensors, the one or more force sensors, the memory device, and the communications device are assembled on a printed circuit board, the printed-circuit board subsequently being mounted on the pin-lifter test substrate.

18. A substrate-processing system, comprising:
a substrate-holding device having a plurality of substrate pin-lifters;
a controller communicatively coupled to the substrate-holding device and having executable instructions configured to:
load, using an end effector of a robot, a pin-lifter test substrate onto the substrate-holding device within at least one process chamber of the substrate-processing system;
receive data from a plurality of motion sensors and a plurality of force sensors mounted on the pin-lifter test substrate, the motion sensors including at least one type of sensor selected from sensor types including inclinometers and accelerometers; and
perform an operation including at least one type of operation selected from operations including transmitting the received data to a receiver located distal from the pin-lifter test substrate and storing the received data to a memory device mounted on the pin-lifter test substrate.

19. The substrate-processing system of claim 18, wherein the operation of transmitting the received data is configured to be performed wirelessly.

20. The substrate-processing system of claim 18, wherein the controller further includes executable instructions configured to:
keep the end effector of the robot within the process chamber while the pin-lifter test substrate is receiving the data;
command the plurality of substrate pin-lifters to move to a raised, pins-up position, and to a lowered, pins-down position, for a predetermined number of cycles per a predetermined pattern; and
perform an operation including at least one operation selected from wirelessly transmitting the data received from the plurality of substrate pin-lifters by the motion sensors to the receiver located distal from the pin-lifter test substrate and storing the received data to the memory device mounted on the pin-lifter test substrate.

21. The substrate-processing system of claim 18, wherein the controller further includes executable instructions configured to make a determination, based on data received from the raised, pins-up position, and the lowered, pins-down position, whether one or more of the substrate pin-lifters is malfunctioning.

22. The substrate-processing system of claim 18, wherein the controller further includes executable instructions configured to make a determination, based on data received from the raised, pins-up position, and the lowered, pins-down position, whether an air hose coupled to the substrate pin-lifters is malfunctioning.

23. The substrate-processing system of claim 18, wherein the controller further includes executable instructions configured to retract the end effector of the robot from the process chamber during testing with the pin-lifter test substrate after placing the pin-lifter test substrate onto the substrate-holding device.

24. The substrate-processing system of claim 23, wherein the controller further includes executable instructions configured to:
leave an access door to the process chamber in an open position; and
wirelessly transmit the received data from the pin-lifter test substrate to a receiver mounted on the robot.

25. The substrate-processing system of claim 18, wherein the controller further includes executable instructions configured to monitor a dynamic alignment of the pin-lifter test substrate after removing the pin-lifter test substrate from the process chamber based on data received from the plurality of motion sensors.

26. The substrate-processing system of claim 18, wherein the controller further includes executable instructions configured to make a determination, based on data received from the plurality of motion sensors, whether an incline angle of the substrate-holding device is within a specification based on a predetermined value for the incline angle.

27. The substrate-processing system of claim 18, wherein the controller further includes executable instructions configured to make a determination, based on data received from the plurality of motion sensors, whether the substrate pin-lifters are all accelerating similarly based on a predetermined tolerance value for acceleration.

28. A substrate-processing system, comprising:
a process chamber;
a substrate-holding device having a plurality of substrate pin-lifters and located within the process chamber;
a robot having an end effector configured to place substrate on the substrate-holding device;
a pin-lifter test substrate configured to be placed on the substrate-holding device by the end effector of the robot, the pin-lifter test substrate including:
a plurality of motion sensors including at least one type of sensor selected from sensor types including inclinometers and accelerometers;
one or more force sensors located in proximity to corresponding locations of the plurality of substrate pin-lifters when the pin-lifter test substrate is placed on a substrate-holding device; and
a communications device configured to transmit data received from the plurality of motion sensors and the one or more force sensors;
a memory device configured to record data received from the plurality of motion sensors and the one or more force sensors; and
a controller communicatively coupled to the substrate-holding device and the robot having the end effector, the controller having executable instructions configured to control operations of the substrate-processing system related at least to the pin-lifter test substrate.
